(19) United States
(12) Patent Application Publication
(10) Pub. No.: US 2023/0112624 A1
(43) Pub. Date: Apr. 13, 2023

(54) SENSOR DEVICE

(71) Applicant: Sumitomo Wiring Systems, Ltd., Yokkaichi-shi, Mie (JP)

(72) Inventors: Moriyuki SHIMIZU, Yokkaichi-shi, Mie (JP); Masaharu NAKAMURA, Yokkaichi-shi, Mie (JP); Rieko NAGAO, Yokkaichi-shi, Mie (JP); Hiroki MURAMATSU, Yokkaichi-shi, Mie (JP); Koichi KATO, Yokkaichi-shi, Mie (JP); Toshinari KOBAYASHI, Yokkaichi-shi, Mie (JP); Yukitoshi TERASAKA, Yokkaichi-shi, Mie (JP); Kyungwoo KIM, Yokkaichi-shi, Mie (JP)

(21) Appl. No.: 17/907,330

(22) PCT Filed: Mar. 12, 2021
(86) PCT No.: PCT/JP2021/010040

§ 371 Date: Sep. 26, 2022

(30) Foreign Application Priority Data
Mar. 27, 2020 (JP) 2020-057488

(51) Int. Cl. H05K 5/00

(52) U.S. Cl. CPC H05K 5/0095; F16D 66/00

(57) ABSTRACT

An object of the present disclosure is to further improve waterproofness between an end portion of a wiring member and a resin molded portion. A sensor device includes: a sensor element; a wiring member connected to the sensor element; a resin molded portion that covers the sensor element and an end portion of the wiring member; and an annular elastic member that is interposed between an outer periphery of the wiring member and the resin molded portion.

### CROSS-REFERENCE TO RELATED APPLICATIONS

This application is the U.S. national stage of PCT/JP2021/010040 filed on Mar. 12, 2021, which claims priority of Japanese Patent Application No. JP 2020-057488 filed on Mar. 27, 2020, the contents of which are incorporated herein.

### TECHNICAL FIELD

The present disclosure relates to a sensor device.

### BACKGROUND

JP 2017-096828A discloses that a plurality of output electric wire portions are connected to a detection element portion, the plurality of output electric wire portions are bundled as a sheathed electric wire, and the detection element portion and an end portion of the sheathed electric wire are embedded in a resin mold portion.

In a structure in which an end portion of a wiring member is embedded in a resin mold portion, it is desired that waterproofness be further improved between the outer periphery of the wiring member and the resin mold portion.

In view of this, an object of the present disclosure is to further improve waterproofness between an end portion of a wiring member and a resin molded portion.

### SUMMARY

A sensor device of the present disclosure is a sensor device that includes: a sensor element; a wiring member connected to the sensor element; a resin molded portion that covers the sensor element and an end portion of the wiring member; and an annular elastic member that is interposed between an outer periphery of the wiring member and the resin molded portion.

### ADVANTAGEOUS EFFECTS OF DISCLOSURE

According to the present disclosure, it is possible to further improve waterproofness between the end portion of the wiring member and the resin molded portion.

### BRIEF DESCRIPTION OF DRAWINGS

FIG. 1 is a front view of a sensor device according to an embodiment.

FIG. 2 is a cross-sectional view taken along line II-II in FIG. 1.

FIG. 3 is a cross-sectional view taken along line III-III in FIG. 1.

FIG. 4 is an explanatory diagram showing an example of a process of molding a resin molded portion.

FIG. 5 is a cross-sectional view of a sensor device according a modification example.

### DETAILED DESCRIPTION OF PREFERRED EMBODIMENTS

First, embodiments of the present disclosure will be listed and described.

A sensor device of the present disclosure is as follows.

### First Aspect

A sensor device in accordance with a first aspect includes: a sensor element; a wiring member connected to the sensor element; a resin molded portion that covers the sensor element and an end portion of the wiring member; and an annular elastic member that is interposed between an outer periphery of the wiring member and the resin molded portion. According to the sensor device, after the molding of the resin molded portion, even if the wiring member contracts or resin sink marks are formed in the resin molded portion, the annular elastic member deforms to fill a gap between the outer periphery of the wiring member and the resin molded portion. This further improves waterproofness between the end portion of the wiring member and the resin molded portion.

### Second Aspect

In a second aspect of the sensor device, in the sensor device according to the first aspect, the annular elastic member may be formed of a material that more easily elastically deforms than the resin molded portion. This allows the annular elastic member to deform more suitably than the resin molded portion in response to contraction of the wiring member and the formation of sink marks in the resin molded portion.

### Third Aspect

In a third aspect of the sensor device, in the sensor device accordance with the first or the second aspect, an inner peripheral surface of the annular elastic member may be shaped to have a constant-diameter portion that is continuous along an axial direction of the annular elastic member. Accordingly, a large area of the annular elastic member is likely to be joined to the outer periphery of the wiring member. This allows the annular elastic member to easily deform in response to contraction of the wiring member.

### Fourth Aspect

In a fourth aspect of the sensor device, in the sensor device according to any one of the first to the third aspects, the annular elastic member may be adhered to both the wiring member and the resin molded portion. Since the annular elastic member is adhered to both the wiring member and the resin molded portion, the annular elastic member easily deforms in response to contraction of the wiring member and the formation of sink marks in the resin molded portion.

### Fifth Aspect

In a fifth aspect of the sensor device, in the sensor device according to any one of the first to the fourth aspects, a portion in an axial direction of the annular elastic member may be embedded in the resin molded portion, and another portion of the annular elastic member may extend off from the resin molded portion. This makes it possible to mold the resin molded portion in a state where the wiring member is positioned using the other portion of the annular elastic member.

Specific examples of the sensor device in the present disclosure will be described below with reference to the drawings. It should be noted that the present disclosure is not limited to the examples herein, but rather is indicated by the scope of claims, and is intended to include all modifications within a meaning and scope equivalent to the scope of claims.

### Embodiments

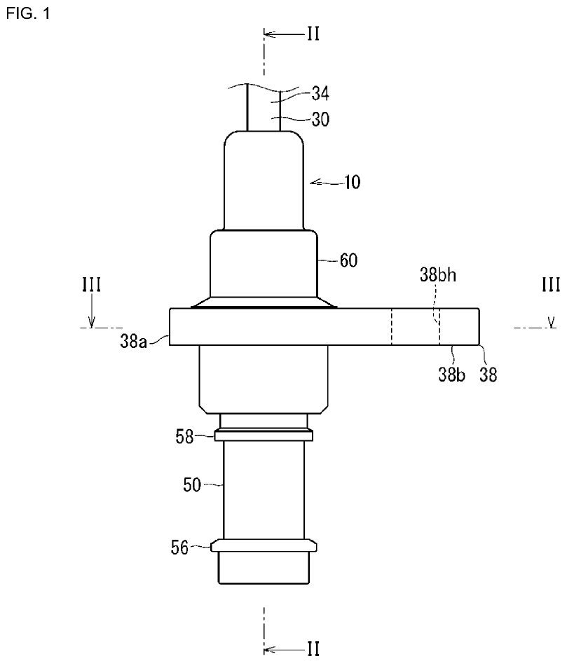

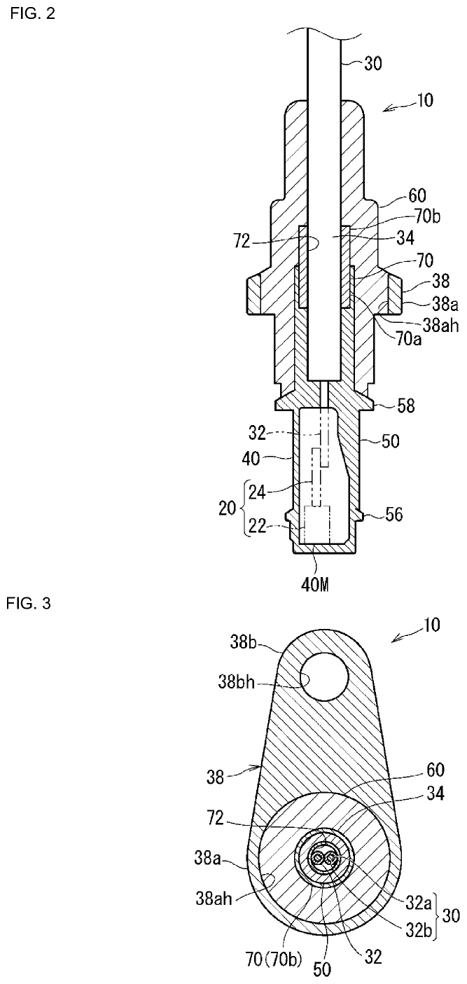

A sensor device according to an embodiment will be described below. FIG. 1 is a front view of a sensor device 10. FIG. 2 is a cross-sectional view taken along line II-II in FIG. 1. FIG. 3 is a cross-sectional view taken along line III-III in FIG. 1. In FIG. 2, a sensor element 20, an inner holder portion 40, and a wiring member 30 are illustrated in outline, not in cross section.

The sensor device 10 includes the sensor element 20, the wiring member 30, a resin molded portion 50, and an annular elastic member 70. The sensor element 20 is connected to the wiring member 30. The resin molded portion 50 covers the sensor element 20 and an end portion of the wiring member 30. The annular elastic member 70 is interposed between the outer periphery of the wiring member 30 and the resin molded portion 50. The annular elastic member 70 fills a gap between the outer periphery of the wiring member 30 and the resin molded portion 50.

More specifically, the sensor element 20 is an element that detects the physical amount of magnetism, light, temperature, or the like or amounts of change thereof. The sensor element 20 includes an element body portion 22 and a lead portion 24. The element body portion 22 is formed in a square shape, for example. The lead portion 24 is an elongated portion formed of metal or the like. The lead portion 24 extends outward from the element body portion 22. An output signal from the sensor element 20 is output to the outside via the lead portion 24. The sensor device 10 is used as a sensor that detects the rotation speed of wheels of a vehicle, for example. More specifically, the sensor device 10 may be used as a sensor for an anti-lock brake system (ABS).

The wiring member 30 is connected to the sensor element 20. The wiring member 30 includes at least one linear conductor. The wiring member 30 includes a plurality of (in this example, two) electric wires 32. Each of the electric wires 32 includes a core wire 32a that is a conductor and an insulating cover 32b that covers the core wire 32a. The plurality of electric wires 32 are bundled and covered by a sheath 34. The sheath 34 is a cover formed of a resin or the like. The plurality of electric wires 32 extend from the end portion of the sheath 34. The core wires 32a are exposed at end portions of the plurality of electric wires 32. The core wires 32a at the respective end portions of the plurality of electric wires 32 are connected to the lead portion 24. The core wires 32a and the lead portion 24 may be connected via soldering or crimping, for example. The wiring member may be one electric wire. The wiring member may be a member in which a plurality of electric wires are bundled in an exposed state without being covered with a sheath.

The resin molded portion 50 covers the sensor element 20 and an end portion of the wiring member 30. In this example, the sensor element 20 and the connection portion between the sensor element 20 and the wiring member 30 are held in a fixed posture by an inner holder portion 40. The inner holder portion 40 is a resin molded portion that is molded with the sensor element 20 and the connection portion between the lead portion and the core wires 32a as an insert, for example. A part in which the sensor element 20 and the connection portion between the sensor element 20 and the wiring member 30 are held by the inner holder portion 40 may be regarded as an intermediate part 40M. Molding the resin molded portion 50 with the intermediate part 40M as an insert allows the sensor element 20 to be embedded in the resin molded portion 50 at a correct position. In addition, molding the resin molded portion 50 so as to cover the inner holder portion 40 enhances waterproofness of the sensor element 20. The inner holder portion 40 is not necessarily required to be a molded part molded with the sensor element 20 and the like as an insert. For example, the inner holder portion 40 may be molded in a shape into which the sensor element 20 and the like are fitted, and the sensor element 20 and the like may be fitted into the inner holder portion 40. The sensor device 10 is not necessarily required to include the inner holder portion 40. The resin molded portion 50 may directly cover the sensor element 20.

The resin molded portion 50 covers the sensor element 20 with the inner holder portion 40 in between. The resin molded portion 50 also covers an end portion of the wiring member 30, specifically an end portion of the sheath 34 in this example. That is, the resin molded portion 50 covers a range from the sensor element 20 to the end portion of the sheath 34.

The resin molded portion 50 has a plurality of (in this example, two) annular protrusions 56 and 58. The first annular protrusion 56 is formed at the position where the element body portion 22 is embedded, so as to protrude outward along the circumferential direction of the resin molded portion 50. The second annular protrusion 58 is formed at a position separated from the sensor element 20 on a side to which the wiring member 30 extends, in this example, at a position between the element body portion 22 and the sheath 34, so as to protrude outward along the circumferential direction of the resin molded portion 50.

In the present embodiment, the resin molded portion 50 is further covered with an additional resin molded portion 60. In this example, a portion of the resin molded portion 50 on the side on which the wiring member 30 extends is covered with the additional resin molded portion 60. More specifically, the additional resin molded portion 60 covers a portion of the resin molded portion 50 on the side on which the wiring member 30 extends from the annular protrusion 58. The additional resin molded portion 60 extends toward the side on which the wiring member 30 extends relative to the resin molded portion 50, and also covers the sheath 34 of the wiring member 30 extending from the resin molded portion 50.

A fixed portion 38 is fixed to the additional resin molded portion 60. The fixed portion 38 includes a sensor-side fixed portion 38a that is fixed around the additional resin molded portion 60 and a vehicle-side fixed portion 38b that protrudes outward from the sensor-side fixed portion 38a. The sensor-side fixed portion 38a has a through-hole 38ah in which the additional resin molded portion 60 is arranged. The vehicle-side fixed portion 38b has a screwing hole 38bh. The additional resin molded portion 60 is preferably molded with the fixed portion 38 positioned in the mold. This allows the fixed portion 38 to be fixed to an outer peripheral portion of the additional resin molded portion 60. The fixed portion 38 may be fixed to the additional resin molded portion 60 by fitting the additional resin molded portion 60 into the through-hole 38ah in the fixed portion 38.

The additional resin molded portion 60 may be omitted. In this case, the fixed portion 38 may be fixed to the resin molded portion 50. The fixed portion 38 may be omitted.

The annular elastic member 70 is interposed between the outer periphery of the wiring member 30 and the resin molded portion 50. The annular elastic member 70 is a molded component that is formed by molding, for example. The annular elastic member 70 is elastically stretchable such that when the wiring member 30 greatly contracts with respect to the resin molded portion 50, the annular elastic member 70 can stretch along with such contraction so as to fill the gap between the wiring member 30 and the resin molded portion 50. For example, the annular elastic member 70 is formed of a material that more easily elastically deforms than the resin molded portion 50. The ease of elastic deformation may be evaluated by modulus of elasticity. The modulus of elasticity may be the Young's modulus, for example. For example, the Young's modulus of the material constituting the annular elastic member 70 may be smaller than the Young's modulus of the material constituting the resin molded portion 50.

The annular elastic member 70 has a hole 72 through which the wiring member 30 is insertable. The inner peripheral surface of the hole 72 is shaped to be capable of coming into contact with the outer periphery of the wiring member 30, in this example, the entire sheath 34 in the circumferential direction. For example, if the outer periphery of the sheath 34 is circular in shape, the hole 72 is also formed in a circular shape accordingly. The inner peripheral surface of the hole 72 preferably has a shape in which a constant-diameter portion is continuous along the axial direction of the annular elastic member 70, that is, a cylindrical shape. In this case, when the inner peripheral surface of the hole 72 is in contact with the entire wiring member 30 along the peripheral direction, such contact is kept continuous along the longitudinal direction of the wiring member 30.

The outer peripheral shape of the annular elastic member 70 is circular, for example. The outer peripheral shape of the annular elastic member 70 may be another shape such as a square shape or an oval shape, or may be a shape in which a flat, convex, or concave section or the like is provided in a portion of the circle or oval. The outer peripheral shape of the annular elastic member 70 may change along the axial direction. For example, the outer peripheral shape of the annular elastic member 70 may be a shape in which a thick portion and a thin portion are connected together.

The annular elastic member 70 may be attached to the end portion of the sheath 34 of the wiring member 30 by inserting the wiring member 30 into the hole 72 in the annular elastic member 70. In this example, the annular elastic member 70 is attached to the wiring member 30 at a position separated from the opening end portion of the sheath 34.

The thicknesses of the inner peripheral surface and outer peripheral surface of the hole 72 in the annular elastic member 70 are set as desired. For example, the annular elastic member 70 may be the same in thickness as the sheath 34 or may be thicker than the sheath 34 or may be thinner than the sheath 34. If the annular elastic member 70 is thicker, the annular elastic member 70 can more easily deform to fill the gap between the wiring member 30 and the resin molded portion 50. Accordingly, the annular elastic member 70 is preferably thicker than the sheath 34.

The annular elastic member 70 is formed of an elastic material such as urethane, for example. For example, the sheath 34 may be formed of polyurethane or polyethylene terephthalate (PET), the resin molded portion 50 may be formed of nylon or the like, and the annular elastic member 70 may be formed of urethane (for example, thermoplastic polyurethane). The annular elastic member 70 preferably is adhered to both the sheath 34 of the wiring member 30 and the resin molded portion 50. The adhesion here includes adhesion on various principles, for example, adhesion by anchor effect, adhesion by chemical bond, adhesion by mixture of melted substances, and the like.

At least a portion of the annular elastic member 70 is embedded in the resin molded portion 50. In this example, a portion 70a of the annular elastic member 70 closer to one axial end is embedded in the resin molded portion 50. Another portion 70b of the annular elastic member 70 closer to the other axial end extends from the resin molded portion 50.

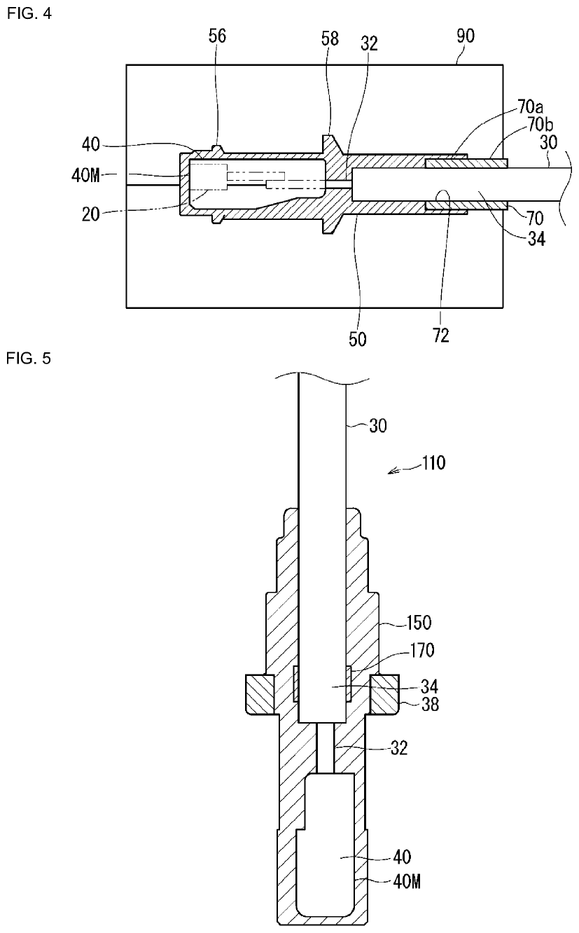

The extension of the portion 70b of the annular elastic member 70 from the resin molded portion 50 provides an advantage that, during the molding of the resin molded portion 50, the wiring member 30 can be positioned using the portion 70b of the annular elastic member 70 as illustrated in FIG. 4. That is, during the molding of the resin molded portion 50, the wiring member 30 extending from the intermediate component 40M is positioned in a mold 90 for molding the resin molded portion 50 while suppressing a resin leakage. At this time, the mold 90 allows the wiring member 30 to be positioned and held via the portion 70b of the annular elastic member 70 while suppressing direct contact with the wiring member 30. Accordingly, even if the annular elastic member 70 is held by a strong force in order to suppress a resin leakage, positioning marks are less likely to be left on the wiring member 30 by the mold. The intermediate component 40M itself is positioned in the mold 90 by separately provided positioning pins or the like.

In the sensor device 10, when the resin molded portion 50 is molded so as to cover the sensor element 20 and the end portion of the wiring member 30, the sheath 34 of the wiring member 30 becomes heated. The heated sheath 34 may thermally expand and then contract. The contraction of the sheath 34 may cause the surface of the sheath 34 to separate from an area of the resin molded portion 50 surrounding the wiring member 30. However, even if the wiring member 30 contracts, the annular elastic member 70 deforms to fill the gap between the outer periphery of the sheath 34 of the wiring member 30 and the resin molded portion 50. This further improves waterproofness between the end portion of the wiring member 30 and the resin molded portion 50.

The annular elastic member 70 also plays the role of suppressing the transfer of heat generated by molding of the resin molded portion 50 to the sheath 34 of the wiring member 30. Since the heat transfer to the sheath 34 is suppressed, the contraction of the sheath 34 after the molding is also suppressed. Accordingly, a gap is unlikely to be created between the resin molded portion 50 and the sheath 34 of the wiring member 30, thereby further improving waterproofness in this respect.

The annular elastic member 70 is formed of a material that more easily elastically deforms than the resin molded portion 50. This allows the annular elastic member 70 to deform more easily than the resin molded portion 50 when the wiring member 30 contracts, thereby bringing about a further improvement in waterproofness.

The inner peripheral surface of the annular elastic member 70 is shaped such that the constant-diameter portion is continuous along the axial direction of the annular elastic member 70. Accordingly, a large area of the annular elastic member 70 can more easily join to the outer periphery of the sheath 34 of the wiring member 30. Thus, the annular elastic member 70 can easily deform so as to be pulled by the contraction of the sheath 34 of the wiring member 30. This further improves waterproofness.

Since the annular elastic member 70 is joined to both the sheath 34 of the wiring member 30 and the resin molded portion 50, the annular elastic member 70 can easily deform so as to be pulled by both the sheath 34 and the resin molded portion 50. This allows the annular elastic member 70 to stretch and more reliably fill the gap between the sheath 34 and the resin molded portion 50, thereby bringing about a further improvement in waterproofness.

Since the portion 70a of the annular elastic member 70 is embedded in the resin molded portion 50 and the other portion 70b of the annular elastic member 70 extends from the resin molded portion 50, the resin molded portion 50 can be molded with the wiring member 30 positioned using the other portion 70b of the annular elastic member 70. Accordingly, positioning marks are likely to be left on the wiring member 30 by the mold.

FIG. 5 is a cross-sectional view of a sensor device 110 according to a modification example. As illustrated in the present modification example, one resin molded portion 150 corresponding to the resin molded portion 50 may cover a range from an intermediate component 40M to an end portion of a wiring member 30 (an end portion of a sheath 34). That is, in the foregoing embodiment, the additional resin molded portion 60 may be omitted. In addition, an annular elastic member 170 corresponding to the annular elastic member 70 may be entirely embedded in the resin molded portion 150.

The components described above in relation to the embodiment and modification examples may be combined as appropriate unless they are contradictory to each other.

1. A sensor device comprising:
a sensor element;
a wiring member connected to the sensor element;
a resin molded portion that covers the sensor element and an end portion of the wiring member; and
an annular elastic member that is interposed between an outer periphery of the wiring member and the resin molded portion.

2. The sensor device according to claim 1, wherein the annular elastic member is formed of a material that more easily elastically deforms than the resin molded portion.

3. The sensor device according to claim 1, wherein an inner peripheral surface of the annular elastic member is shaped to have a constant-diameter portion that is continuous along an axial direction of the annular elastic member.

4. The sensor device according to claim 1, wherein the annular elastic member is adhered to both the wiring member and the resin molded portion.

5. The sensor device according to claim 1, wherein a portion in an axial direction of the annular elastic member is embedded in the resin molded portion, and another portion of the annular elastic member extends from the resin molded portion.

6. The sensor device according to claim 2, wherein an inner peripheral surface of the annular elastic member is shaped to have a constant-diameter portion that is continuous along an axial direction of the annular elastic member.

7. The sensor device according to claim 2, wherein the annular elastic member is adhered to both the wiring member and the resin molded portion.

8. The sensor device according to claim 3, wherein the annular elastic member is adhered to both the wiring member and the resin molded portion.

9. The sensor device according to claim 2, wherein a portion in an axial direction of the annular elastic member is embedded in the resin molded portion, and another portion of the annular elastic member extends from the resin molded portion.

10. The sensor device according to claim 3, wherein a portion in an axial direction of the annular elastic member is embedded in the resin molded portion, and another portion of the annular elastic member extends from the resin molded portion.

11. The sensor device according to claim 4, wherein a portion in an axial direction of the annular elastic member is embedded in the resin molded portion, and another portion of the annular elastic member extends from the resin molded portion.
